(19) United States
(12) Patent Application Publication
(10) Pub. No.: US 2017/0018408 A1
(43) Pub. Date: Jan. 19, 2017

(54) USE OF SINTERED NANOGRAINED YTTRIUM-BASED CERAMICS AS ETCH CHAMBER COMPONENTS

(71) Applicant: Lam Research Corporation, Fremont, CA (US)

(72) Inventors: Lin XU, Katy, TX (US); Hong SHIH, Walnut, CA (US); John DAUGHERTY, Fremont, CA (US); Satish SRINIVASAN, Newark, CA (US); Siwen LI, San Jose, CA (US)

(21) Appl. No.: 14/800,583

(22) Filed: Jul. 15, 2015

(51) Int. Cl. H01J 37/32; B32B 38/00; B32B 18/00; B32B 37/24; C01F 17/00; C04B 35/64

(52) U.S. Cl. CPC H01J 37/32495; C01F 17/0043; C01F 17/0062; C01F 17/0012; H01J 37/32715; H01J 37/32009; C04B 35/64; B32B 18/00; B32B 37/24; B32B 38/00; C04B 2235/963; C04B 2235/616; C04B 2235/3217; C04B 2235/3225; B32B 2250/02; B32B 2307/538; B32B 2038/0068; B32B 2315/02

(57) ABSTRACT

In accordance with this disclosure, there are provided several inventions, including an apparatus and method for creating a plasma resistant part, which may be formed of a sintered nanocrystalline ceramic material comprising yttrium, oxide, and fluoride. Example parts thus made may include windows, edge rings, or injectors. In one configuration, the parts may be yttria co-sintered with alumina, which may be transparent.

### BACKGROUND

This disclosure relates to the use and manufacture of sintered nanograined components in plasma chambers for semiconductor processing.

Advanced coatings such as yttria (Y₂O₃) are indispensable for state-of-the-art plasma etch chambers. Y₂O₃ is a widely used plasma facing material due to its chemical inertness and low erosion rate in plasmas. However, advanced Y₂O₃ coatings cannot cover all the applications. For example, a high-bias etch process in a plasma processing chamber may require an edge ring with a Y₂O₃ coating as thick as 1 mm. This may not be economical, and there may be engineering constraints that make such a thick coating impractical. For example, a thick coating subjected to high stress may delaminate even prior to chamber service. Therefore, a more useful edge ring might comprise a sintered ring made from solid Y₂O₃.

However, the use of a traditional solid, sintered Y₂O₃ edge ring, using micrometer-scale Y₂O₃ powders, has significant problems. There are fundamental technical difficulties in obtaining pore free, pure Y₂O₃ solid faces. For example, Y₂O₃ has very high melting point; therefore, pore free sintering of pure Y₂O₃ is very difficult. In addition, the sinterability of micro-sized Y₂O₃ powder is poor, and thus the sintering process at high temperature is prolonged. This long sintering process may lead to uncontrolled grain growth which may further deteriorate the mechanical performance of sintering Y₂O₃ compacts. Y₂O₃ ceramics are inherently weak compared to alumina (Al₂O₃) and other common ceramic materials that might alternatively be used in plasma chambers, such as sapphire, aluminum oxynitride (AlON), partially stabilized zirconia (PSZ), or spinel, etc., in terms of both flexural strength and fracture toughness. Related yttrium-containing materials may present similar difficulties.

FIG. 1 illustrates a representative surface morphology of a sintered Y₂O₃ edge ring 100 with grain size of approximately 5-10 μm. There are some surface pits 101 clearly visible. Without being limited by any particular theory, the origin of the defects could come from porosity in the Y₂O₃, or grain pullout during machining due to poor mechanical strength. These surface defects may lead to concerns about the possibility of loose surface Y₂O₃ particles, especially for those interfaces under rubbing or heavily handling. In other contexts, one approach to increase sintering density and lower sintering temperature might be to add low melting temperature sintering aids such as Mg/Si/Ca oxides. In the plasma processing context, however, this strategy may lead to metal contamination concerns.

New ways are therefore needed to take advantage of the properties of Y₂O₃ and related yttrium materials in plasma chambers.

### SUMMARY

Disclosed herein are various embodiments, which provide plasma resistant parts adapted for use in a plasma processing chamber which is configured to produce a plasma while in an operating mode. The part comprises a plasma-facing surface configured to face the plasma when the plasma chamber is in the operating mode, wherein the surface is formed of a sintered nanocrystalline ceramic material comprising yttrium in addition to oxide and/or fluoride.

In another manifestation, an embodiment provides a method of forming a co-sintered nanocrystalline part. A first green compact is formed from a first ceramic material. A second green compact is formed from nanocrystals of a second ceramic material comprising yttrium in addition to oxide and/or fluoride. The first green compact and the second green compact are co-sintered.

These and other features of the present inventions will be described in more detail below in the detailed description and in conjunction with the following figures.

### BRIEF DESCRIPTION OF THE DRAWINGS

The disclosed inventions are illustrated by way of example, and not by way of limitation, in the figures of the accompanying drawings and in which like reference numerals refer to similar elements and in which:

FIG. 1 is a scanning electron micrograph of a sintered Y₂O₃ surface with grain size of about 5-10 μm.

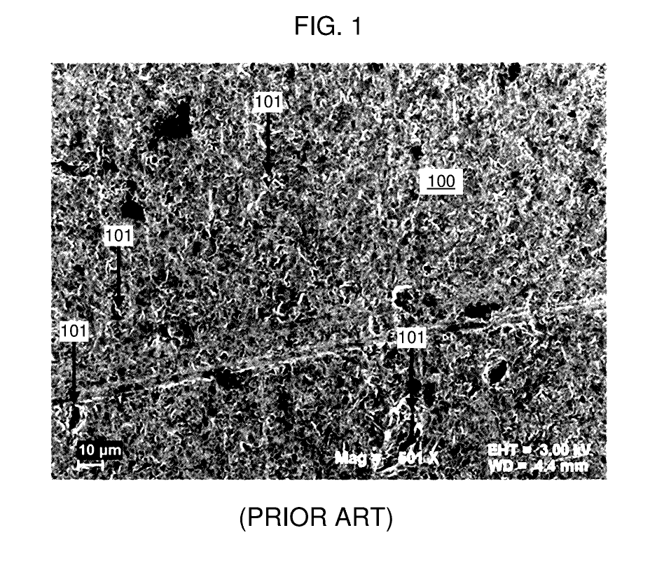

FIG. 2 is a schematic cross-sectional view of a two-layer co-sintered structure facing a plasma in a plasma chamber.

FIG. 3 schematically illustrates an example of a plasma processing chamber which may be used in an embodiment.

### DETAILED DESCRIPTION

Inventions will now be described in detail with reference to a few of the embodiments thereof as illustrated in the accompanying drawings. In the following description, specific details are set forth in order to provide a thorough understanding of the present invention. However, the present invention may be practiced without some or all of these specific details, and the disclosure encompasses modifications which may be made in accordance with the knowledge generally available within this field of technology. Well-known process steps and/or structures have not been described in detail in order to not unnecessarily obscure the present disclosure.

As used herein, the term “nanograined” or “nanocrystalline” refers to a material that is formed of grains or crystals in the nanometer size range, meaning smaller than a micron. Sizes in the nanometer range may include, for example, 500 nm, 200 nm, 100 nm, 50 nm, 20 nm, or smaller. The term “microcrystalline” refers to a material that is formed of grains or crystals in the micron size range, meaning at least one micron.

Nanograined yttrium-containing ceramics such as Y₂O₃ may be used to fabricate plasma chamber components. Such components may have benefits that include long lifetime in aggressive etch conditions. Such ceramics can be made dense and pure, by sintering.

Nanograined yttrium-containing ceramics may have many advantages in the context of plasma processing. These include mechanical strength in an inverse relationship to grain size, resistance to particle flaking, plasma resistance, and increased lifetime. In addition, cleaning may be easier, because it may be possible to use aggressive cleaning methods such as mechanical cleaning or polishing. In addition, where surfaces are normally a sink for reactive components, a nanograined ceramic surface may be textured, which may increase surface area and may help the adhesion of etch by-products. In one example, starting from a homogenous green compact of Y₂O₃ nanopowders, pure and dense solid Y₂O₃ blanks with enhanced strength can be synthesized through advanced sintering methods. Such a high quality Y₂O₃ ceramic can be further precision-machined to create standalone plasma chamber components. In one example, they can form hybrid components with Y₂O₃ as the plasma-facing “skin.” This may occur through, for example, bonding or green state co-firing.

In another example, such ceramics may be surface textured with a broad spectrum of length scales. In one example, this may be carried out on nanograined Y₂O₃ solids using dilute roughening acid such as HCl.

Chamber components made from dense, nanograined solid Y₂O₃ should offer unique productivity advantages under some extremely challenging applications in etch chambers.

In one example, non-agglomerated nanometer size Y₂O₃ powder may be used to synthesize dense, pure, nano-grained Y₂O₃ for etch chamber applications. This may achieve submicron (or sub-500 nm, sub-200 nm or even smaller range) grain size on final sintering products. Sintering strategies without grain coarsening may be chosen, as the subsequent densification of sintering. The green compact without aggregate of particles may also be used. Large-scale and cost effective synthesis of Y₂O₃ nanoparticles (for example, through combustion methods known in the art) and novel sintering methods (for example, two-step sintering, hot isostatic pressing (HIP), spark plasma sintering (SPS), etc.) may enable the fabrication of relatively large size and dome-shaped transparent Y₂O₃ ceramic optics and very strong armor-like materials.

For use in a plasma chamber application, transparent polycrystalline ceramics may exhibit high density and high purity, superior mechanical robustness, and small nanometer range grains. Nano-size Y₂O₃ powder may significantly enhance the sinterability of Y₂O₃ green body, enabling the sintering of pure and dense compacts at lower temperature and shortened time. Reduction in grain size significantly enhance the material strength following a well-known relationship that mechanical strength is proportional to the square root of grain size. With the grain size further shrunk down to nanometer scale (e.g., sub-200 nm), the flexural strength of nanograined Y₂O₃ may be as strong as the Al₂O₃ ceramic, which in certain applications may typically be in the range of about 300-400 MPa.

Thanks to a number of unique benefits of nanograined Y₂O₃, some applications in etch chambers can be easily envisioned. First, a solid Y₂O₃ edge ring or a solid Y₂O₃ injector may be precision machined from nanograined Y₂O₃ for better particle performance. The use of solid Y₂O₃ for an edge ring or injector with large grain size has not been desirable, due to particle concerns in some applications with stringent defect requirements.

In a second embodiment, a nanograined Y₂O₃ sheet may be cofired or bonded onto Al₂O₃ ceramic window to construct laminated TCP window. For example, a green sheet of nanosize Y₂O₃ powders can be co-sintered with Al₂O₃ green sheet to form hybrid structures with Y₂O₃ exposed to plasmas. Alternatively, a fully sintered nanograined Y₂O₃ sheet may be bonded (for example, through glass frit or polymer adhesive bonding) to an Al₂O₃ window. In one embodiment, the bonding layer may be designed to be outside the vacuum. Such a hybrid may combine the benefits of Al₂O₃ ceramic (e.g., high resistivity, low loss tangent, low cost, and/or better thermal conductivity) with the benefits of plasma-facing, nano-grained Y₂O₃ ceramic sheet (e.g., purity, density, relative thickness). A thicker Y₂O₃ laminated layer may in one embodiment provide the option of using more aggressive clean chemistries and more aggressive refurbishment process for some very “dirty” etch processes.

The formation of nanocrystalline layers as described herein has advantages over the formation of such layers by other means, such as plasma spraying, which may result in the formation of a fluffy structure with significant voids and pores, lack of uniformity, and compromised strength and durability.

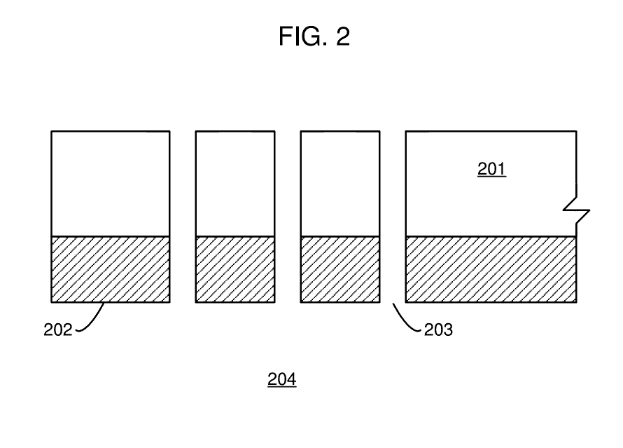

FIG. 2 is a schematic illustration of a cross-section of a hybrid part for a plasma chamber. In this example, layer 201 is an Al₂O₃ window, bonded to a nanocrystalline Y₂O₃ layer 202 which faces a plasma 204. The hybrid structure may contain injector holes 203 for injection of a gas into a plasma chamber. These holes may in one embodiment be part of the green part(s) before sintering or co-sintering, or in another embodiment they may be machined into the part after sintering. In this embodiment, the layers 201 and 202 may each be on the order of about 1-10 millimeters in width, of smaller or larger depending on the application and, if the part is sintered, the minimum thickness required to form a sintered product by methods known in the art. Other hybrid parts of a plasma processing chamber may be formed, with similar two-layer structure.

A third embodiment is a plasma resistant viewport, which may be transparent in a range of interest, such as optical or UV. Plasma resistant, monocrystalline transparent Y₂O₃, is a deep UV transmitter. Nanograined Y₂O₃ may in one embodiment provide superior plasma resistant window materials for endpoint sensors, such as optical emission spectrometers (OES) under aggressive plasma etch conditions. The size and geometry of polycrystalline transparent Y₂O₃ viewports may not be limited, as single crystal sapphire windows may be.

In other embodiments, other plasma resistant monolithic ceramic components may also be sintered if the nanosized powders of interest are readily available. Such material candidates may include AlON (which is commercially available for building bullet proof armors), YF₃, ZrO₂, YAG, YOF, etc.

In other embodiments, a nanocrystalline ceramic component may be textured by increasing its roughness and surface area. Because micrograined ceramic materials may have grains in a range such as 5-10 microns, it becomes impractical to create surfaces features at or below that scale. In one particular embodiment, for a grain size in the range of 20-100 nm (for example, around 50 nm), surface roughness features and bumps may be a similar size range, resulting in a finely-textured surface.

The inventors have determined that HCl acid percolation through grain boundary is a one of the major roughening mechanisms for certain types of nanocrystaline Y₂O₃. Without being limited by theory, this roughening mechanism may be applicable on the sintered, nanograined monolithic Y₂O₃.

For example, a nanocrystalline ceramic component can be textured in a controlled manner to a surface roughness (Ra) in the range 0.02-0.1 μm using dilute acids such as HCl. Surface texturing in a highly controlled manner may be important to ensure non-drift etch process and good adhesion of precoat and/or etch byproducts.

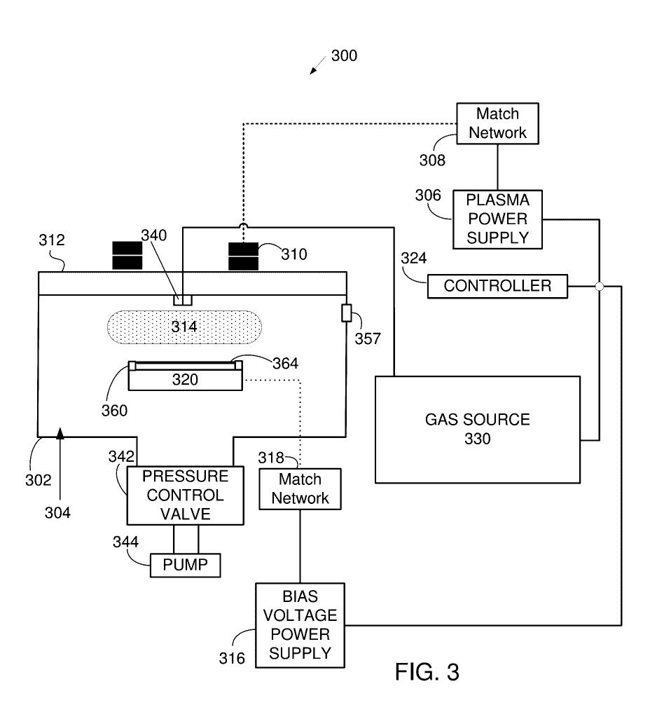

To facilitate understanding, FIG. 3 schematically illustrates an example of a plasma processing chamber 300 which may be used in an embodiment. The plasma processing chamber 300 includes a plasma reactor 302 having a plasma processing confinement chamber 304 therein. A plasma power supply 306, tuned by a match network 308, supplies power to a TCP coil 310 located near a power window 312 to create a plasma 314 in the plasma processing confinement chamber 304 by providing an inductively coupled power. The TCP coil (upper power source) 310 may be configured to produce a uniform diffusion profile within the plasma processing confinement chamber 304. For example, the TCP coil 310 may be configured to generate a toroidal power distribution in the plasma 314. The power window 312 is provided to separate the TCP coil 310 from the plasma processing confinement chamber 304 while allowing energy to pass from the TCP coil 310 to the plasma processing confinement chamber 304. A wafer bias voltage power supply 316 tuned by a match network 318 provides power to an electrode 320 to set the bias voltage on the substrate 364 which is supported by the electrode 320. A controller 324 sets points for the plasma power supply 306, gas source/gas supply mechanism 330, and the wafer bias voltage power supply 316.

The plasma power supply 306 and the wafer bias voltage power supply 316 may be configured to operate at specific radio frequencies such as, for example, 33.56 MHz, 27 MHz, 2 MHz, 60 MHz, 400 kHz, 2.54 GHz, or combinations thereof. Plasma power supply 306 and wafer bias voltage power supply 316 may be appropriately sized to supply a range of powers in order to achieve desired process performance. For example, in one embodiment of the present invention, the plasma power supply 306 may supply the power in a range of 50 to 5000 Watts, and the wafer bias voltage power supply 316 may supply a bias voltage of in a range of 20 to 2000 V. In addition, the TCP coil 310 and/or the electrode 320 may be comprised of two or more sub-coils or sub-electrodes, which may be powered by a single power supply or powered by multiple power supplies.

As shown in FIG. 3, the plasma processing chamber 300 further includes a gas source/gas supply mechanism 330. The gas source 330 is in fluid connection with plasma processing confinement chamber 304 through a gas inlet, such as a gas injector 340. The gas injector 340 may be located in any advantageous location in the plasma processing confinement chamber 304, and may take any form for injecting gas. The process gases and byproducts are removed from the plasma process confinement chamber 304 via a pressure control valve 342 and a pump 344, which also serve to maintain a particular pressure within the plasma processing confinement chamber 304. The pressure control valve 342 can maintain a pressure of less than 1 Torr during processing. An edge ring 360 is placed around the wafer 364. The gas source/gas supply mechanism 330 is controlled by the controller 324. The plasma reactor 302 may have a plasma resistant viewport 357. A Kiyo by Lam Research Corp. of Fremont, Calif., may be used to practice an embodiment.

While inventions have been described in terms of several preferred embodiments, there are alterations, permutations, and various substitute equivalents, which fall within the scope of this invention. There are many alternative ways of implementing the methods and apparatuses disclosed herein. It is therefore intended that the following appended claims be interpreted as including all such alterations, permutations, and various substitute equivalents as fall within the true spirit and scope of the present invention.

What is claimed is:

1. A plasma resistant part adapted for use in a plasma processing chamber which is configured to produce a plasma while in an operating mode, wherein the part comprises a plasma-facing surface configured to face the plasma when the plasma chamber is in the operating mode, wherein the surface is formed of a sintered nanocrystalline ceramic material comprising yttrium in addition to oxide and/or fluoride.

2. The plasma resistant part of claim 1, wherein the ceramic material comprises Y₂O₃.

3. The plasma resistant part of claim 1, wherein the ceramic material comprises YF₃ or YOF.

4. The plasma resistant part of claim 1, wherein the part is an edge ring.

5. The plasma resistant part of claim 1, wherein the part is a gas injector.

6. The plasma resistant part of claim 1, further comprising a first layer and a second layer that are co-sintered together, and wherein the plasma-facing surface is part of the second layer, and the second layer is a nanocrystalline ceramic material.

7. The plasma resistant part of claim 6, wherein the first layer is a microcrystalline ceramic material.

8. The plasma resistant part of claim 7, wherein the first layer comprises alumina.

9. The plasma resistant part of claim 7, wherein the plasma resistant part is a window.

10. A plasma processing apparatus comprising the plasma resistant part of claim 1, further comprising:
the plasma processing chamber; and
a substrate support,
wherein the plasma resistant part is situated in the plasma processing chamber, such that its plasma-facing surface faces the plasma when the plasma chamber is in its operating mode.

11. The plasma processing apparatus of claim 10, further comprising a first layer and a second layer that are co-sintered together, and wherein the plasma-facing surface is part of the second layer, and the second layer is a nanocrystalline ceramic material, wherein the first layer is a microcrystalline ceramic material.

12. A method of forming a co-sintered nanocrystalline part, comprising:
forming a first green compact of a first ceramic material;
forming a second green compact of nanocrystals of a second ceramic material comprising yttrium in addition to oxide and/or fluoride; and
co-sintering the first green compact and the second green compact.

13. The method of claim 12, wherein the first ceramic material is alumina.

14. The method of claim 12, wherein the first green compact is formed of nanocrystals of the first ceramic material.

15. The method of claim 12, further comprising subjecting the surface to an acid such that the surface roughness (Ra) increases such that it is within a range of 0.02-1 μm.

16. The method of claim 12, further comprising adapting the part for use in a plasma processing chamber which is configured to produce plasma while in an operating mode, and wherein the part has a plasma-facing side that faces the plasma that faces the plasma when the part is situated in the chamber and the chamber is in the operating mode.

17. The method of claim 16, wherein the part is a transparent window.

18. The method of claim 16, wherein the part is an edge ring.
